(19) United States
(12) Patent Application Publication
(10) Pub. No.: US 2021/0349143 A1
(43) Pub. Date: Nov. 11, 2021

(54) DISPLAY PANEL DETECTION METHOD AND DETECTION DEVICE

(71) Applicant: HKC CORPORATION LIMITED, Shenzhen (CN)

(72) Inventor: HuaiLiang HE, Shenzhen (CN)

(21) Appl. No.: 16/326,919

(22) PCT Filed: Nov. 26, 2018
(86) PCT No.: PCT/CN2018/117354

§ 371 Date: Feb. 21, 2019

(30) Foreign Application Priority Data
Nov. 7, 2018 (CN) 201811316619.8

(51) Int. Cl. G01R 31/28; G02F 1/13

(52) U.S. Cl. CPC G01R 31/282; G02F 1/1309

(57) ABSTRACT

The present application discloses a display panel detection method and detection device. The detection method includes steps of: sending at least one to-be-detected panel to a first detection machine for detection; and sending the at least one to-be-detected panel to a second detection machine for second detection; and returning the at least one to-be-detected panel to a corresponding cassette.

This application claims priority to Chinese Patent Application No. CN201811316619.8, filed with the Chinese Patent Office on Nov. 7, 2018, and entitled “DISPLAY PANEL DETECTION METHOD AND DETECTION DEVICE”, which is incorporated herein by reference in its entirety.

### TECHNICAL FIELD

The present application relates to the field of display technologies, and more specifically, to a display panel detection method and detection device.

### BACKGROUND

The descriptions herein merely provide background information related to the present application, and do not necessarily constitute the prior art.

With development and progress of science and technologies, liquid crystal displays have become mainstream products of displays because of hotspots such as thin body, power saving, and low radiation, and various types of displays are widely applied to various aspects in life. A plurality of detections are performed on a display panel and a glass substrates and the like forming the display panel before delivery. Using a detection device consisting of a cassette and two detection machines as an example, one of the machines performs abnormality detection. An abnormal to-be-detected object is sent to the other detection machine for deep detection, to determine the problem. However, in a detection device known to the inventor, the abnormal to-be-detected object is generally returned to the cassette after being detected by the one detection machine, and then is determined by a related staff. The staff sends a to-be-detected object to the other detection machine for second detection after manually selecting the to-be-detected object for second detection. Such a setting not only results in low detection efficiency, but also results in high human costs.

How to provide a detection method with high detection efficiency is a problem urgently needs to be resolved by a person skilled in the art.

### SUMMARY

The present application provides a display panel detection method and detection device, to improve detection efficiency.

To achieve the foregoing objective, the present application provides a display panel detection method, including steps of:

sending at least one to-be-detected panel to a first detection machine for detection;

generating, by the first detection machine, a detection result;

determining, by a pipeline control system, whether the detection result is abnormal, if the detection result is abnormal, determining that the at least one to-be-detected panel is abnormal, and sending the at least one to-be-detected panel to a second detection machine for second detection; and

returning the at least one to-be-detected panel to a corresponding cassette.

Optionally, the step of determining, by the pipeline control system, whether the detection result is abnormal, and if the detection result is abnormal, sending the at least one to-be-detected panel to the second detection machine for the second detection includes the following process:

when the detection result is abnormal, sending, by a conveying apparatus, the at least one to-be-detected panel directly from the first detection machine to the second detection machine for the second detection.

Optionally, the step of determining, by the pipeline control system, whether the detection result is abnormal, and if the detection result is abnormal, sending the at least one to-be-detected panel to the second detection machine for the second detection includes the following process:

automatically sending, by the conveying apparatus after returning the at least one to-be-detected panel to the cassette, the at least one to-be-detected panel whose detection result is abnormal to the second detection machine for the second detection, where

a detection project of the first detection and a detection project of the second detection are the same.

Optionally, the process of automatically sending, by the conveying apparatus after returning the at least one to-be-detected panel to the cassette, the at least one to-be-detected panel whose detection result is abnormal to the second detection machine for the second detection includes:

each time the cassette retrieves one to-be-detected panel, determining whether a corresponding detection result is abnormal, and if the detection result is abnormal, sending the to-be-detected panel to the second detection machine for the second detection.

Optionally, the process of automatically sending, by the conveying apparatus after returning the at least one to-be-detected panel to the cassette, the at least one to-be-detected panel whose detection result is abnormal to the second detection machine for the second detection includes:

each time the cassette retrieves a batch of the to-be-detected panels, determining whether a corresponding detection result is abnormal, and if the detection result is abnormal, sending the abnormal to-be-detected panels to the second detection machine for the second detection.

Optionally, after the step of generating a detection result, if the detection result is normal, it is determined that the at least one to-be-detected panel is qualified, and the at least one to-be-detected panel is directly returned to a qualified-product cassette, where

abnormal determining corresponding to the first detection at least includes: when it is detected that the detected panel has an open circuit or a short circuit, determining that the first detection is abnormal; and abnormal determining corresponding to the second detection at least includes: when it is detected that a segment of a circuit or an interface of the detected panel has an open circuit or a short circuit, determining that the second detection is abnormal.

The step of returning the at least one to-be-detected panel to the corresponding cassette specifically includes:

after the second detection operation is completed, analyzing a second detection result, and returning a to-be-detected panel whose second detection result is abnormal to an abnormal-product cassette; and returning a normal to-be-detected panel to a qualified-product cassette.

Optionally, after the step of determining, by the pipeline control system, whether the detection result is abnormal, and if the detection result is abnormal, sending the at least one to-be-detected panel to the second detection machine for the second detection, the method further includes:

if a detection result obtained through the second detection is normal, returning the at least one to-be-detected panel to a qualified-product cassette.

The present application further discloses a display panel detection method, including steps of:

sending at least one to-be-detected panel to a first detection machine for detection;

generating, by the first detection machine, a detection result;

determining, by a pipeline control system, whether the detection result is abnormal; and if the detection result is normal, determining that the at least one to-be-detected panel is qualified, and returning, by a conveying apparatus, the at least one qualified to-be-detected panel to a qualified-product cassette; or if the detection result is abnormal, determining that the at least one to-be-detected panel is abnormal, and sending, by a conveying apparatus, the at least one to-be-detected panel directly from the first detection machine to a second detection machine for second detection; and

determining whether a detection result obtained through the second detection is abnormal; and if the detection result is normal, determining that the at least one to-be-detected panel is qualified, and returning, by the conveying apparatus, the at least one qualified to-be-detected panel to the qualified-product cassette; or if the detection result is abnormal, determining that the at least one to-be-detected panel is abnormal, and returning, by the conveying apparatus, the at least one to-be-detected panel to an abnormal-product cassette.

The present application further discloses a detection device, including:

a cassette, configured to: load at least one to-be-detected panel, and retrieve a detected panel;

a first detection machine, configured to detect the at least one to-be-detected panel;

a second detection machine, configured to perform second detection on the at least one to-be-detected panel;

a pipeline controller, configured to: install a pipeline control system, determine a detection result of the at least one to-be-detected panel, and send the at least one to-be-detected panel whose detection result is abnormal from the first detection machine to the second detection machine for the second detection; and a conveying apparatus, configured to: send the at least one to-be-detected panel from the first detection machine to the second detection machine, or return the at least one to-be-detected panel to a corresponding cassette.

According to the detection method in the present application, after a detection result of at least one to-be-detected panel on which detection performed by a first detection machine is completed is determined, a pipeline control system directly controls an abnormal to-be-detected panel (which is determined through detection) to be sent to a second detection machine for second detection, so as to further determine a detection status of the to-be-detected panel. Because after the to-be-detected panel is returned to a cassette, the detected abnormal to-be-detected panel is sent to the second detection machine for the second detection without an instruction of a related staff, manual operations are reduced, detection efficiency is improved, and human costs are reduced.

### BRIEF DESCRIPTION OF DRAWINGS

The drawings are included to provide optional understanding of embodiments of the present application, which constitute a part of the specification and illustrate the embodiments of the present application, and describe the principles of the present application together with the text description. Apparently, the accompanying drawings in the following description show merely some embodiments of the present application, and a person of ordinary skill in the art may still derive other accompanying drawings from these accompanying drawings without creative efforts.

In the accompanying drawings:

FIG. 1 is a flowchart of a display panel detection method according to an embodiment of the present application;

FIG. 2 is another flowchart of a display panel detection method according to an embodiment of the present application; and

FIG. 3 is a schematic diagram of a display panel detection device according to another embodiment of the present application.

### DETAILED DESCRIPTION

To make a person skilled in to art understand the technical solutions in the present application better, the following clearly and completely describes the technical solutions in the embodiments of the present application with reference to the accompanying drawings in the embodiments of the present application. Apparently, the described embodiments are merely some but not all of the embodiments of the present application. All other embodiments obtained by a person of ordinary skill in the art based on the embodiments of the present application without creative efforts shall fall within the protection scope of the present application.

The following describes the present application with reference to the accompanying drawings and optional embodiments.

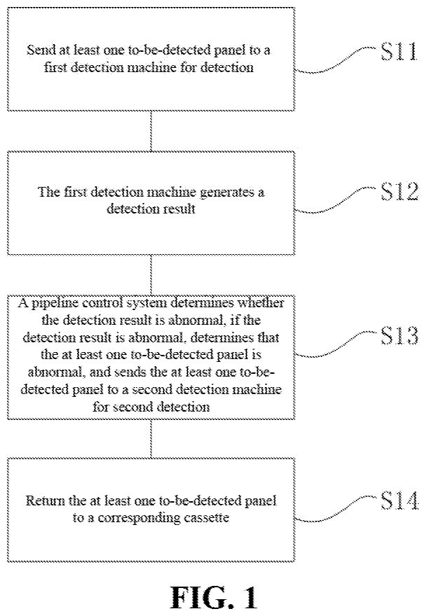

FIG. 1 is a flowchart of a display panel detection method according to the present application. Referring to FIG. 1, the present application provides a display panel detection method, including steps of:

S11: Send at least one to-be-detected panel to a first detection machine for detection.

S12: The first detection machine generates a detection result.

S13: A pipeline control system determines whether the detection result is abnormal, if the detection result is abnormal, determines that the at least one to-be-detected panel is abnormal, and sends the at least one to-be-detected panel to a second detection machine for second detection.

S14: Return the at least one to-be-detected panel to a corresponding cassette.

According to the detection method in the present application, after a detection result of at least one to-be-detected panel on which detection performed by a first detection machine is completed is determined, a pipeline control system directly controls an abnormal to-be-detected panel (which is determined through detection) to be sent to a second detection machine for second detection, so as to determine a detection problem of the to-be-detected panel. Because after the to-be-detected panel is returned to a cassette, the detected abnormal to-be-detected panel is sent to the second detection machine for the second detection without an instruction of a related staff, manual operations are reduced, detection efficiency is improved, and human costs are reduced.

The display panel in the present application may be an entire display panel, or may be a part of components of a display panel, such as a glass substrate in the display panel.

A quantity of detection projects of a detection projection may be one or more. Using an open/short circuit test as an example, which is also referred to as a continuity test or a contact test, a main purpose of the test is to determine whether a pin of a circuit in a to-be-tested panel is correctly connected to an internal circuit, and determine that no pin or circuit has an open circuit or a circuit.

Detection projects of the first detection machine and the second detection machine may be the same, or may be not completely the same. Specifically, the detection projects of the first detection machine and the second detection machine may be selected according to a specific situation. For example, the detection project of the second detection machine may be reinforced or upgraded based on the detection project of the first machine. Using an open/short circuit test as an example, the first detection machine may only detect whether there is an open circuit or a short circuit, and a locating function is added to the second detection machine, to locate a location of the open circuit or the short circuit, but detection projects of the second detection include all detection projects of the first detection.

In an embodiment, the step S13 of determining, by the pipeline control system, whether the detection result is abnormal, and if the detection result is abnormal, sending the at least one to-be-detected panel to the second detection machine for the second detection includes the following process:

when the detection result is abnormal, sending, by a conveying apparatus, the at least one to-be-detected panel directly from the first detection machine to the second detection machine for the second detection, where a detection project of the first detection and a detection project of the second detection are the same.

In this solution, if the pipeline control system considers that a to-be-detected panel detected by the first detection machine needs the second detection, the pipeline control system sends the to-be-detected panel directly from the first detection machine to the second detection machine for the second detection without retuning the to-be-detected panel to the cassette. In such a setting, not only human costs are reduced, but also processes of manual determining and selection are saved, thereby improving detection efficiency. Specifically, a transport device, such as a transport belt, may be constructed between the first detection machine and the second detection machine, and then the pipeline control system controls switching of the transport device, to return the to-be-detected panel to the cassette or send the to-be-detected panel to the second detection machine.

In an embodiment, the step S13 of determining, by the pipeline control system, whether the detection result is abnormal, and if the detection result is abnormal, sending the at least one to-be-detected panel to the second detection machine for the second detection includes the following process:

automatically sending, by the conveying apparatus after returning the at least one to-be-detected panel to the cassette, the at least one to-be-detected panel whose detection result is abnormal to the second detection machine for the second detection.

In this solution, if the pipeline control system considers that a to-be-detected panel detected by the first detection machine needs the second detection, the pipeline control system directly sends the to-be-detected panel that is abnormal and needs the second detection to the second detection machine for the second detection after sending the to-be-detected panel to the cassette. In such a setting, not only human costs are reduced, but also processes of manual determining and selection are saved, thereby improving detection efficiency. In addition, the existing pipeline basically can be used because of such a design, thereby saving costs in reconstructing the pipeline. Specifically, a switching gear may be set at the cassette, and the pipeline control system controls switching, to return the to-be-detected panel to the cassette for storing or send the to-be-detected panel to the second detection machine.

In an embodiment, the process of automatically sending, by the pipeline control system after returning the at least one to-be-detected panel to the cassette, the at least one to-be-detected panel whose detection result is abnormal to the second detection machine for the second detection includes:

each time the cassette retrieves one to-be-detected panel, determining whether a corresponding detection result is abnormal, and if the detection result is abnormal, sending the to-be-detected panel to the second detection machine for the second detection.

In this solution, each time the cassette receives one to-be-detected panel returned by the first detection machine, the cassette determines whether a detection result is abnormal, and if detection result is abnormal, immediately sends the to-be-detected panel to the second detection machine for the second detection, thereby avoiding a problem of low detection efficiency caused due to accumulation of to-be-detected panels at the cassette.

In an embodiment, the process of automatically sending, by the pipeline control system after returning the at least one to-be-detected panel to the cassette, the at least one to-be-detected panel whose detection result is abnormal to the second detection machine for the second detection includes:

each time the cassette retrieves a batch of the to-be-detected panels, determining whether a corresponding detection result is abnormal, and if the detection result is abnormal, sending the abnormal to-be-detected panels to the second detection machine for the second detection.

In this solution, the cassette determines an abnormal to-be-detected panel of a batch of to-be-detected panels by using a batch as a unit, and sends a batch of abnormal to-be-detected panels to the second detection machine for the second detection. Detection performed in batches avoids a problem of chaos, and facilitates subsequent management.

In an embodiment, after the step S12 of generating the detection result, if the detection result is normal, it is determined that the at least one to-be-detected panel is qualified, and the at least one to-be-detected panel is directly returned to a qualified-product cassette.

Abnormal determining corresponding to the first detection at least includes: when it is detected that the detected panel has an open circuit or a short circuit, determining that the first detection is abnormal; and abnormal determining corresponding to the second detection at least includes: when it is detected that a segment of a circuit or an interface of the detected panel has an open circuit or a short circuit, determining that the second detection is abnormal. Specifically, in this solution, a detection value corresponding to each detection project may further be determined. When the detection value exceeds a normal value range, the detection result is determined to be abnormal.

In this solution, when a detection result of a to-be-detected panel is normal, or the detection is qualified, the to-be-detected panel is returned to the qualified-product cassette for subsequent arrangement and storing works.

In an embodiment, in the step of determining, by the pipeline control system, whether the detection result is abnormal, if the detection result is abnormal, determining that the at least one to-be-detected panel is abnormal, and sending the at least one to-be-detected panel to the second detection machine for the second detection, when the detection result is normal, the at least one to-be-detected panel is still sent to the second detection machine for the second detection.

The step of returning the at least one to-be-detected panel to the corresponding cassette specifically includes:

after the second detection operation is completed, analyzing the two detection results, and returning an abnormal to-be-detected panel to an abnormal-product cassette; and returning a normal to-be-detected panel to the qualified-product cassette.

In this solution, to reduce procedures, it is set that a detection result is not determined, and a to-be-detected panel is sent to the second detection machine for detection regardless the detection result, provided that the to-be-detected panel has been detected by the first detection machine. In this way, a calculation amount of the pipeline control system can be reduced, that is, the pipeline control system only needs to have a more basic function of determining that the at least one to-be-detected panel has been detected by the first detection machine, and does not need to have more calculation and determining capabilities, thereby reducing hardware requirements of the detection method, reducing costs, avoiding a problem of incorrect determining caused because a detection result is incorrect, and improving product yield.

In an embodiment, in the step of sending the at least one to-be-detected panel to the second detection machine for the second detection, the at least one to-be-detected panel is sent to the second detection machine for the second detection regardless of the detection result of the at least one to-be-detected panel.

The step of returning the at least one to-be-detected panel to the corresponding cassette specifically includes:

after the second detection operation is completed, analyzing a second detection result, and returning a to-be-detected panel whose second detection result is abnormal to the abnormal-product cassette; and returning a normal to-be-detected panel to the qualified-product cassette.

In this solution, the first detection may have an incorrect detection result, and a purpose of the second detection is to prevent a qualified product from being processed as scrap.

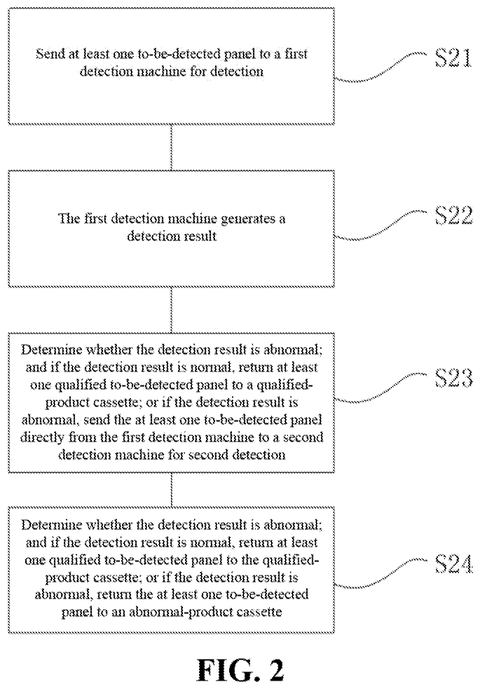

FIG. 2 is another flowchart of a display panel detection method according to the present application. Referring to FIG. 2 with reference to FIG. 1, as can be known, the present application further discloses a display panel detection method, including steps of:

S21: Send at least one to-be-detected panel to a first detection machine for detection.

S22: The first detection machine generates a detection result.

S23: A pipeline control system determines whether the detection result is abnormal; and if the detection result is normal, determines that the at least one to-be-detected panel is qualified, and a conveying apparatus returns the at least one qualified to-be-detected panel to a qualified-product cassette; or if the detection result is abnormal, the pipeline control system determines that the at least one to-be-detected panel is abnormal, and a conveying apparatus sends the at least one to-be-detected panel directly from the first detection machine to a second detection machine for second detection.

S24: Determine whether a detection result obtained through the second detection is abnormal; and if the detection result is normal, determine that the at least one to-be-detected panel is qualified, and the conveying apparatus returns the at least one qualified to-be-detected panel to the qualified-product cassette; or if the detection result is abnormal, determine that the at least one to-be-detected panel is abnormal, and the conveying apparatus returns the at least one to-be-detected panel to an abnormal-product cassette.

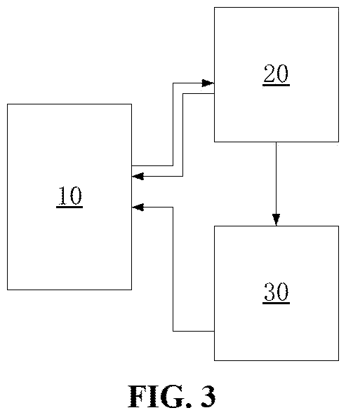

FIG. 3 is a schematic diagram of a display panel detection device according to the present application. Referring to FIG. 3 with reference to FIG. 1 and FIG. 2, as can known, the present application further discloses a detection device, including: a cassette 10, configured to: load at least one to-be-detected panel (not shown in the figure), and retrieve a detected panel;

a first detection machine 20, configured to detect the at least one to-be-detected panel;

a second detection machine 30, configured to perform second detection on the at least one to-be-detected panel;

a pipeline controller (not shown in the figure), configured to: install a pipeline control system, determine a detection result of the at least one to-be-detected panel, and send the at least one to-be-detected panel whose detection result is abnormal from the first detection machine to the second detection machine for the second detection; and

a conveying apparatus (not shown in the figure), configured to: send the at least one to-be-detected panel from the first detection machine to the second detection machine, or return the at least one to-be-detected panel to a corresponding cassette.

A panel in the present application may be a twisted nematic (TN) panel, an in-plane switching (IPS), or a multi-domain vertical alignment (VA) panel, and certainly, may be an organic light-emitting diode (OLED) panel, a quantum dot light emitting display (QLED) panel, or another type of suitable panel.

The foregoing describes optional specific embodiments of the present application in detail. It should be understood that a person of ordinary skill in the art can make various modifications and changes according to the idea of the present application without creative efforts. Therefore, all technical solutions that can be obtained by a person skilled in the art through logic analysis, deduction, or limited experiment based on the idea of the present application shall fall within the protection scope determined by the claims.

What is claimed is:

1. A display panel detection method, comprising steps of:
sending at least one to-be-detected panel to a first detection machine for detection;
generating, by the first detection machine, a detection result;
determining, by a pipeline control system, whether the detection result is abnormal, if the detection result is abnormal, determining that the at least one to-be-detected panel is abnormal, and sending the at least one to-be-detected panel to a second detection machine for second detection; and
returning the at least one to-be-detected panel to a corresponding cassette.

2. The display panel detection method according to claim 1, wherein the step of determining, by the pipeline control system, whether the detection result is abnormal, and if the detection result is abnormal, sending the at least one to-be-detected panel to the second detection machine for the second detection comprises the following process:
when the detection result is abnormal, sending, by a conveying apparatus, the at least one to-be-detected panel directly from the first detection machine to the second detection machine for the second detection, wherein
a detection project of the first detection and a detection project of the second detection are the same.

3. The display panel detection method according to claim 1, wherein the step of determining, by the pipeline control system, whether the detection result is abnormal, and if the detection result is abnormal, sending the at least one to-be-detected panel to the second detection machine for the second detection comprises the following process:
automatically sending, by the conveying apparatus after returning the at least one to-be-detected panel to the cassette, the at least one to-be-detected panel whose detection result is abnormal to the second detection machine for the second detection, wherein
a detection project of the first detection and a detection project of the second detection are the same.

4. The display panel detection method according to claim 3, wherein the process of automatically sending, by the conveying apparatus after returning the at least one to-be-detected panel to the cassette, the at least one to-be-detected panel whose detection result is abnormal to the second detection machine for the second detection comprises:
each time the cassette retrieves one to-be-detected panel, determining whether a corresponding detection result is abnormal, and if the detection result is abnormal, sending the to-be-detected panel to the second detection machine for the second detection.

5. The display panel detection method according to claim 3, wherein the process of automatically sending, by the conveying apparatus after returning the at least one to-be-detected panel to the cassette, the at least one to-be-detected panel whose detection result is abnormal to the second detection machine for the second detection comprises:
each time the cassette retrieves a batch of the to-be-detected panels, determining whether a corresponding detection result is abnormal, and if the detection result is abnormal, sending the abnormal to-be-detected panels to the second detection machine for the second detection.

6. The display panel detection method according to claim 1, wherein in the step of determining, by the pipeline control system, whether the detection result is abnormal, if the detection result is abnormal, determining that the at least one to-be-detected panel is abnormal, and sending the at least one to-be-detected panel to the second detection machine for the second detection, when the detection result is normal, the at least one to-be-detected panel is still sent to the second detection machine for the second detection; and
the step of returning the at least one to-be-detected panel to the corresponding cassette specifically comprises:
after the second detection operation is completed, analyzing a second detection result, and returning a to-be-detected panel whose second detection result is abnormal to an abnormal-product cassette; and returning a normal to-be-detected panel to a qualified-product cassette.

7. The display panel detection method according to claim 1, wherein after the step of determining, by the pipeline control system, whether the detection result is abnormal, and if the detection result is abnormal, sending the at least one to-be-detected panel to the second detection machine for the second detection, the method further comprises:
if a detection result obtained through the second detection is normal, returning the at least one to-be-detected panel to a qualified-product cassette.

8. The display panel detection method according to claim 1, wherein the step of determining, by the pipeline control system, whether the detection result is abnormal, and if the detection result is abnormal, sending the at least one to-be-detected panel to the second detection machine for the second detection comprises the following process:
when the detection result is abnormal, sending, by a conveying apparatus, the at least one to-be-detected panel directly from the first detection machine to the second detection machine for the second detection, wherein
a detection project of the first detection and a detection project of the second detection are the same; and
after the step of generating a detection result, if the detection result is normal, determining that the at least one to-be-detected panel is qualified, and directly returning the at least one to-be-detected panel to a qualified-product cassette, wherein
abnormal determining corresponding to the first detection at least comprises: when it is detected that the detected panel has an open circuit or a short circuit, determining that the first detection is abnormal; and abnormal determining corresponding to the second detection at least comprises: when it is detected that a segment of a circuit or an interface of the detected panel has an open circuit or a short circuit, determining that the second detection is abnormal.

9. The display panel detection method according to claim 1, wherein the step of determining, by the pipeline control system, whether the detection result is abnormal, and if the detection result is abnormal, sending the at least one to-be-detected panel to the second detection machine for the second detection comprises the following process:
automatically sending, by the conveying apparatus after returning the at least one to-be-detected panel to the cassette, the at least one to-be-detected panel whose detection result is abnormal to the second detection machine for the second detection, wherein
a detection project of the first detection and a detection project of the second detection are the same; and
after the step of generating a detection result, if the detection result is normal, determining that the at least one to-be-detected panel is qualified, and directly returning the at least one to-be-detected panel to a qualified-product cassette, wherein
abnormal determining corresponding to the first detection at least comprises: when it is detected that the detected panel has an open circuit or a short circuit, determining that the first detection is abnormal; and abnormal determining corresponding to the second detection at least comprises: when it is detected that a segment of a circuit or an interface of the detected panel has an open circuit or a short circuit, determining that the second detection is abnormal.

10. The display panel detection method according to claim 1, wherein the step of determining, by the pipeline control system, whether the detection result is abnormal, and if the detection result is abnormal, sending the at least one to-be-detected panel to the second detection machine for the second detection comprises the following process:
automatically sending, by the conveying apparatus after returning the at least one to-be-detected panel to the cassette, the at least one to-be-detected panel whose detection result is abnormal to the second detection machine for the second detection, wherein
a detection project of the first detection and a detection project of the second detection are the same; and
after the step of generating a detection result, if the detection result is normal, determining that the at least one to-be-detected panel is qualified, and directly returning the at least one to-be-detected panel to a qualified-product cassette, wherein
abnormal determining corresponding to the first detection at least comprises: when it is detected that the detected panel has an open circuit or a short circuit, determining that the first detection is abnormal; and abnormal determining corresponding to the second detection at least comprises: when it is detected that a segment of a circuit or an interface of the detected panel has an open circuit or a short circuit, determining that the second detection is abnormal.

11. The display panel detection method according to claim 10, wherein the process of automatically sending, by the conveying apparatus after returning the at least one to-be-detected panel to the cassette, the at least one to-be-detected panel whose detection result is abnormal to the second detection machine for the second detection comprises:
each time the cassette retrieves one to-be-detected panel, determining whether a corresponding detection result is abnormal, and if the detection result is abnormal, sending the to-be-detected panel to the second detection machine for the second detection; and
after the step of generating a detection result, if the detection result is normal, determining that the at least one to-be-detected panel is qualified, and directly returning the at least one to-be-detected panel to a qualified-product cassette, wherein
abnormal determining corresponding to the first detection at least comprises: when it is detected that the detected panel has an open circuit or a short circuit, determining that the first detection is abnormal; and abnormal determining corresponding to the second detection at least comprises: when it is detected that a segment of a circuit or an interface of the detected panel has an open circuit or a short circuit, determining that the second detection is abnormal.

12. The display panel detection method according to claim 10, wherein the process of automatically sending, by the conveying apparatus after returning the at least one to-be-detected panel to the cassette, the at least one to-be-detected panel whose detection result is abnormal to the second detection machine for the second detection comprises:
each time the cassette retrieves a batch of the to-be-detected panels, determining whether a corresponding detection result is abnormal, and if the detection result is abnormal, sending the abnormal to-be-detected panels to the second detection machine for the second detection; and
after the step of generating a detection result, if the detection result is normal, determining that the at least one to-be-detected panel is qualified, and directly returning the at least one to-be-detected panel to a qualified-product cassette, wherein
abnormal determining corresponding to the first detection at least comprises: when it is detected that the detected panel has an open circuit or a short circuit, determining that the first detection is abnormal; and abnormal determining corresponding to the second detection at least comprises: when it is detected that a segment of a circuit or an interface of the detected panel has an open circuit or a short circuit, determining that the second detection is abnormal.

13. A display panel detection method, comprising steps of:
sending at least one to-be-detected panel to a first detection machine for detection;
generating, by the first detection machine, a detection result;
determining, by a pipeline control system, whether the detection result is abnormal; and if the detection result is normal, determining that the at least one to-be-detected panel is qualified, and returning, by a conveying apparatus, the at least one qualified to-be-detected panel to a qualified-product cassette; or if the detection result is abnormal, determining that the at least one to-be-detected panel is abnormal, and sending, by a conveying apparatus, the at least one to-be-detected panel directly from the first detection machine to a second detection machine for second detection; and
determining whether a detection result obtained through the second detection is abnormal; and if the detection result is normal, determining that the at least one to-be-detected panel is qualified, and returning, by the conveying apparatus, the at least one qualified to-be-detected panel to the qualified-product cassette; or if the detection result is abnormal, determining that the at least one to-be-detected panel is abnormal, and returning, by the conveying apparatus, the at least one to-be-detected panel to an abnormal-product cassette.

14. A display panel detection device, comprising:
a cassette, configured to: load at least one to-be-detected panel, and retrieve a detected panel;
a first detection machine, configured to perform first detection the at least one to-be-detected panel;
a second detection machine, configured to perform second detection on the at least one to-be-detected panel;
a pipeline controller, configured to: install a pipeline control system, determine a detection result of the at least one to-be-detected panel, and send the at least one to-be-detected panel whose detection result is abnormal from the first detection machine to the second detection machine for the second detection; and
a conveying apparatus, configured to: send the at least one to-be-detected panel from the first detection machine to the second detection machine, or return the at least one to-be-detected panel to a corresponding cassette.

15. The display panel detection device according to claim 14, wherein the step of determining, by the pipeline control system, whether the detection result is abnormal, and if the detection result is abnormal, sending the at least one to-be-detected panel to the second detection machine for the second detection comprises the following process:
when the detection result is abnormal, sending, by a conveying apparatus, the at least one to-be-detected panel directly from the first detection machine to the second detection machine for the second detection, wherein
a detection project of the first detection and a detection project of the second detection are the same.

16. The display panel detection device according to claim 14, wherein the step of determining, by the pipeline control system, whether the detection result is abnormal, and if the detection result is abnormal, sending the at least one to-be-detected panel to the second detection machine for the second detection comprises the following process:
automatically sending, by the conveying apparatus after returning the at least one to-be-detected panel to the cassette, the at least one to-be-detected panel whose detection result is abnormal to the second detection machine for the second detection, wherein
a detection project of the first detection and a detection project of the second detection are the same.

17. The display panel detection device according to claim 16, wherein the process of automatically sending, by the conveying apparatus after returning the at least one to-be-detected panel to the cassette, the at least one to-be-detected panel whose detection result is abnormal to the second detection machine for the second detection comprises:
each time the cassette retrieves one to-be-detected panel, determining whether a corresponding detection result is abnormal, and if the detection result is abnormal, sending the to-be-detected panel to the second detection machine for the second detection.

18. The display panel detection device according to claim 16, wherein the process of automatically sending, by the conveying apparatus after returning the at least one to-be-detected panel to the cassette, the at least one to-be-detected panel whose detection result is abnormal to the second detection machine for the second detection comprises:
each time the cassette retrieves a batch of the to-be-detected panels, determining whether a corresponding detection result is abnormal, and if the detection result is abnormal, sending the abnormal to-be-detected panels to the second detection machine for the second detection.
